(19) United States
(12) Patent Application Publication
(10) Pub. No.: US 2014/0158531 A1
(43) Pub. Date: Jun. 12, 2014

(54) SPUTTERING APPARATUS

(71) Applicant: SAMSUNG DISPLAY CO., LTD., Yongin-City (KR)

(72) Inventor: Jai-Hyuk CHOI, Yongin-City (KR)

(73) Assignee: SAMSUNG DISPLAY CO., LTD., Yongin-City (KR)

(21) Appl. No.: 14/087,226

(22) Filed: Nov. 22, 2013

(30) Foreign Application Priority Data
Dec. 6, 2012 (KR) 10-2012-0141247

(51) Int. Cl. C23C 14/35; C23C 14/34

(52) U.S. Cl. CPC C23C 14/352; C23C 14/3407
USPC 204/298.12

(57) ABSTRACT

A sputtering apparatus includes a sputtering unit, an unwinding unit, a winding unit, and a fixing frame. The sputtering unit forms a layer on a sheet. The unwinding unit continuously supplies the sheet to the sputtering unit. The winding unit continuously receives the sheet from the sputtering unit. The sputtering unit includes a first target, a second target, and a magnetic field generator. The second target is spaced apart from the first target in a first direction. The first target and the second target are facing each other. The magnetic field generator is disposed behind each of the first target and the second target. The fixing frame surrounds a space between the first target and the second target. The fixing frame rotates about an axis extending in the first direction.

### CROSS-REFERENCE TO RELATED APPLICATION

Korean Patent Application No. 10-2012-0141247 filed on Dec. 6, 2012 in the Korean Intellectual Property Office (KIPO), is incorporated herein by reference in its entirety.

### BACKGROUND

1. Field

Example embodiments relate to a sputtering apparatus. More particularly, example embodiments relate to a faced target sputtering apparatus.

2. Description of the Related Art

There are sputtering methods used for forming inorganic layers such as metal layers, transparent conductive layers, or the like. In these sputtering methods, a rare gas, e.g., argon (Ar) gas, is introduced into a vacuum chamber, and a direct current (DC) voltage or a radio frequency (RF) voltage of more than 150 V is supplied to a cathode including a sputtering target, and a layer is formed through slow discharge of the gas.

Sputtering methods are generally used in a layer forming process during manufacturing of flat panel display (FPD) devices, such as to form a thin film transistor (TFT) of a liquid crystal display (LCD) device or an organic light emitting display device, or various other electronic devices. These sputtering methods are classified as dry process techniques, and have a wide range of applications.

### SUMMARY

According to example embodiments, there is provided a sputtering apparatus including a sputtering unit, an unwinding unit, a winding unit, and a fixing frame. The sputtering unit forms a layer on a sheet. The unwinding unit continuously supplies the sheet to the sputtering unit. The winding unit continuously receives the sheet from the sputtering unit. The sputtering unit includes a first target, a second target, and a magnetic field generator. The second target is spaced apart from the first target in a first direction. The first target and the second target are facing each other. The magnetic field generator is disposed behind each of the first target and the second target. The fixing frame surrounds a space between the first target and the second target. The fixing frame rotates about an axis extending in the first direction.

In example embodiments, the fixing frame may support the sheet, and the sheet may be transported by a rotation of the fixing frame.

In example embodiments, the fixing frame may be disposed between the sheet and the space.

In example embodiments, the fixing frame may include a lower portion having a ring-shape, an upper portion having a ring-shape and at least two connection portions connecting the lower portion with the upper portion. The lower portion, the upper portion, and the connection portions may define a plurality of openings.

In example embodiments, the lower portion, the upper portion, and the connection portions may be integral.

In example embodiments, the sheet may be exposed by the openings of the fixing frame to the space between the first target and the second target.

In example embodiments, the sheet may be exposed to more than 50% of a periphery of the space.

In example embodiments, each of the first target and the second target may have a circular planar shape.

In example embodiments, the rotation axis of the fixing frame may meet at a center of the first target and a center of the second target.

In example embodiments, each of the first target and the second target may have an elliptical planar shape or a polygonal planar shape.

In example embodiments, the sheet may surround above 80% of a periphery of the fixing frame.

In example embodiments, each of the unwinding unit and the winding unit may include a roller rotating about an axis extending in the first direction.

In example embodiments, a shield may be provided adjacent the fixing frame where the sheet does not surround the fixing frame.

According to example embodiments, there is provided a sputtering apparatus including a first sputtering unit, a second sputtering unit, an unwinding unit, a winding unit, and a fixing frame. The first sputtering unit forms a first layer on a first surface of a sheet, and the second sputtering unit forms a second layer on a second surface of the sheet. The unwinding unit continuously supplies the sheet to the first sputtering unit. The winding unit continuously receives the sheet from the first sputtering unit. The first sputtering unit includes a first target, a second target, and a magnetic field. The second target is spaced apart from the first target in a first direction. The first target and the second target are facing each other. The magnetic field generator is disposed behind each of the first target and the second target. The fixing frame surrounds a space between the first target and the second target. The fixing frame rotates about an axis extending in the first direction.

In example embodiments, the fixing frame may support the sheet. The sheet may be transported by a rotation of the fixing frame. The sheet may surround above about 80% of a side of the fixing frame.

In example embodiments, the fixing frame may include a lower portion having a ring-shape, an upper portion having a ring-shape and at least two connection portions connecting the lower portion with the upper portion. The lower portion, the upper portion and the connection portions may define a plurality of openings.

In example embodiments, the first surface of the sheet may be exposed by the openings of the fixing frame to the space between the first target and the second target.

In example embodiments, each of the first target and the second target may have a circular planar shape, an elliptical planar shape or a polygonal planar shape.

In example embodiments, the second sputtering unit may include a third target, a fourth target spaced apart from the third target in a second direction substantially perpendicular to the first direction, the first target and the second target facing each other and a magnetic field generator disposed behind each of the first target and the second target.

According to example embodiments, a sputtering apparatus may include a sputtering unit, an unwinding unit and a winding unit for continuously transporting a sheet. The sputtering unit may include a fixing frame, a first target and a second target, which may face each other and may be spaced apart from each other. The fixing frame surrounding a space between the first target and the second target may support the sheet, so that the sheet may surround above about 50% of the side of the space. Therefore, waste of the target material may be reduced, and a space for the sputtering apparatus may be saved by using a relatively large area of the side of the space between the first target and the second target. Further, the sheet may be continuous supplied, so that the sputtering speed may be improved.

### BRIEF DESCRIPTION OF THE DRAWINGS

FIG. 1 is a plan view illustrating a sputtering apparatus in accordance with example embodiments;

FIG. 2 is a cross-sectional view illustrating a sputtering apparatus in accordance with example embodiments;

FIG. 3 is a perspective view illustrating a fixing frame of a sputtering apparatus in accordance with example embodiments;

FIG. 4 is a plan view illustrating a sputtering apparatus in accordance with example embodiments;

FIG. 5 is a plan view illustrating a sputtering apparatus in accordance with example embodiments; and

FIG. 6 is a plan view illustrating a sputtering apparatus in accordance with example embodiments.

### DETAILED DESCRIPTION

Various example embodiments will be described more fully hereinafter with reference to the accompanying drawings, in which some example embodiments are shown. These embodiments may, however, be embodied in many different forms and should not be construed as limited to the example embodiments set forth herein. Rather, these example embodiments are provided so that this disclosure will be thorough and complete, and will fully convey the scope to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings herein. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

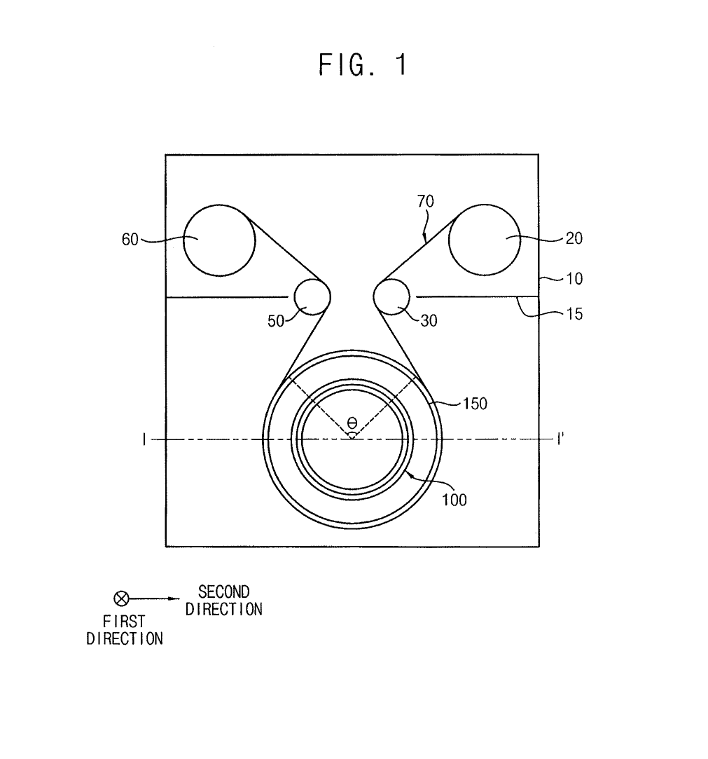

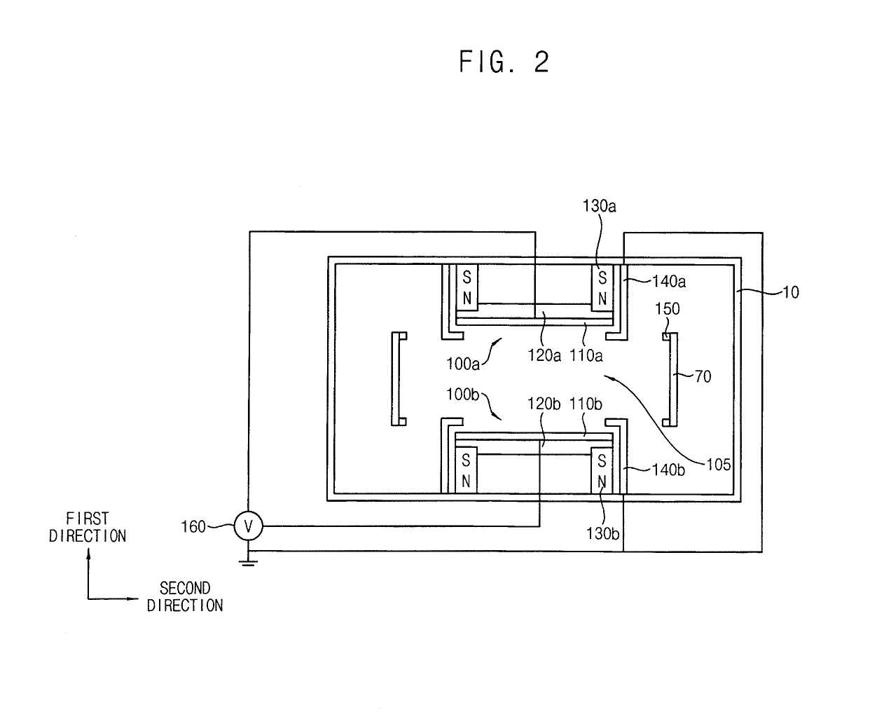

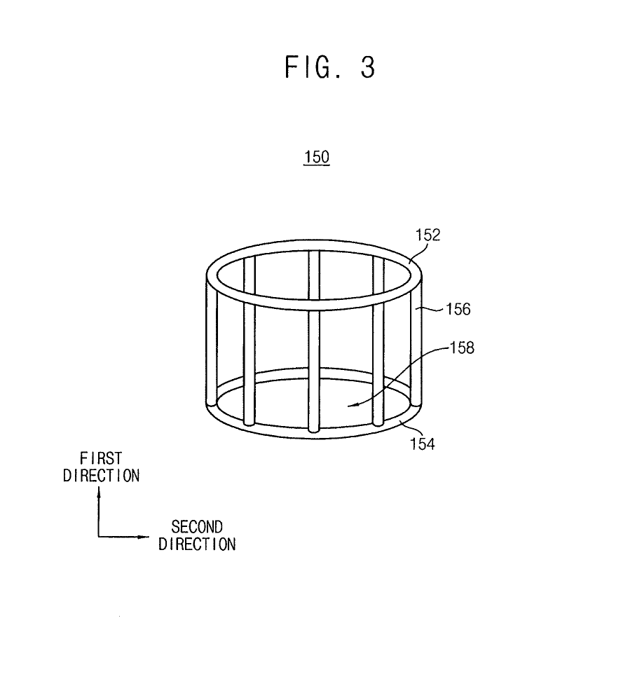

FIG. 1 is a plan view illustrating a sputtering apparatus in accordance with example embodiments. FIG. 2 is a cross-sectional view illustrating a sputtering apparatus in accordance with example embodiments. FIG. 3 is a perspective view illustrating a fixing frame of a sputtering apparatus in accordance with example embodiments.

Referring to FIG. 1, the sputtering apparatus may include a vacuum chamber 10, an unwinding unit 20, a winding unit 60, a sputtering unit 100, and a fixing frame 150.

The vacuum chamber 10 may be divided into a first region and a second region. The sputtering unit 100 may be disposed in the first region of the vacuum chamber 10, and the unwinding unit 20 and the winding unit 60 may be disposed in the second region of the vacuum chamber 10. Further, a partition wall 15 may be disposed in the vacuum chamber 10 to separate the first region and the second region. The vacuum chamber 10 may be connected to a vacuum pump (not illustrated), thereby maintaining an inner space thereof at a vacuum pressure. The vacuum chamber 10 may surround and protect other element of the sputtering apparatus.

The unwinding unit 20 may serve to supply a sheet 70 to the sputtering unit 100. In example embodiments, the unwinding unit 20 may include a rotation shaft and the sheet 70 may be wound around the rotation shaft. As the rotation shaft rotates about an axis extending a first direction, the sheet 70 may be continuously transported from the unwinding unit 20 to the sputtering unit 100.

The sputtering unit 100 may form a layer on the sheet 70, which may be supplied from the unwinding unit 20. In example embodiments, the sputtering unit 100 may include facing targets. The constitution of the sputtering unit 100 will be described with reference to FIG. 2. The constitution of the fixing frame 150 will be described with reference to FIG. 3.

The winding unit 60 may serve to receive the sheet 70 from the sputtering unit 100. In example embodiments, the winding unit 60 may include a rotation shaft which may be connected to a motor (not illustrated). As the rotation shaft rotates about the axis extending the first direction, the sheet 70 may be wound around the winding unit 60.

In example embodiments, the sheet 70 may have a predetermined width and may extend in a direction. Further, the sheet 70 may include a material having a predetermined flexibility. For example, the sheet 70 may include polyethylene terephthalate (PET), polyethylene naphthalate (PEN), polyamide (PA), polycarbonate (PC), polyether sulfone (PES), polyimide (PI), etc. Particularly, a plasma generated in the sputtering unit 100 may not touch at the sheet 70, so that the sheet 70 does not need to have a resistance to the plasma.

Between the unwinding unit 20 and the winding unit 60, a plurality of supporting rollers may be disposed to guide the sheet 70. In example embodiments, a first supporting roller 30 may be disposed between the unwinding unit 20 and the sputtering unit 100, and a second supporting roller 50 may be disposed between the sputtering unit 100 and the winding unit 60. The sputtering apparatus may be depicted to include two supporting rollers 30 and 50 in FIG. 1, however the embodiments may not be limited thereto. For example, at least four supporting rollers may be disposed between the unwinding unit 20 and the winding unit 60.

The first and second supporting rollers 30 and 50 may rotate about the axis extending in the first direction. Therefore, the sheet 70 may be transported, while contacting side walls of the first and second supporting rollers 30 and 50.

The first and second supporting rollers 30 and 50 may be disposed adjacent to each other, and a distance between the first and second supporting rollers 30 and 50 may be smaller than the width of the sputtering unit 100, i.e., taken along a second direction. The first and second supporting rollers 30 and 50 may apply tension to the sheet 70, so that the sheet 70 may make tight contact with a side wall of the sputtering unit 100.

In example embodiments, the sputtering unit 100 may form a layer on a surface of the sheet 70 continuously, so that process time and cost may be saved.

Referring to FIG. 2, the sputtering unit 100 may include a first target structure 100a and a second target structure 100b.

In particular, the first target structure 100a may include a first target 110a, a first supporting portion 120a, a first magnetic field generator 130a and a first shield portion 140a, and the second target structure 100b may include a second target 110b, a second supporting portion 120b, a second magnetic field generator 130b and a second shield portion 140b. In example embodiments, each of the first target structure 100a and the second target structure 100b may have a circular planar shape.

The first target 110a and the second target 110b may include a material which may be deposited on the surface on the sheet 70. In some example embodiments, the first target 110a and the second target 110b may include a metal, e.g., aluminum, molybdenum, copper, gold, platinum, or an alloy thereof for forming a source electrode, a drain electrode, or a gate electrode of a thin film transistor, or a cathode electrode or an anode electrode of light emitting structure in an organic light emitting diode or a liquid crystal display device. In other example embodiments, the first target 110a and the second target 110b may include ITO (Indium-Tin Oxide), IZO (Indium-Zinc Oxide), (Indium Oxide), ZnO, TZO (Tin-Zinc Oxide), AZO, GZO, and so forth for forming an anode electrode or a cathode electrode of a light emitting structure in an organic light emitting diode.

The first target 110a and the second target 110b may be disposed to face each other. In this case, surfaces facing and adjacent to each other may be defined as front surfaces of the first target 110a and the second target 110b, and rear surfaces may be opposed to the front surfaces.

The first supporting portion 120a and the second supporting portion 120b may be disposed on rear surfaces of the first target 110a and the second target 110b, respectively. That is, the first and second supporting portions 120a and 120b may be disposed behind the first and second targets 110a and 110b. The first and second supporting portions 120a and 120b may support the first and second targets 110a and 110b, and also may receive the first and second magnetic field generators 130a and 130b. The first and second supporting portions 120a and 120b may include an insulation material. In example embodiments, the first and second supporting portions 120a and 120b may include additional components (not illustrated) for cooling the first and second targets 110a and 110b. For example, the first and second supporting portions 120a and 120b may include a cooling medium flow path.

The first and second magnetic field generators 130a and 130b may be received in the first and second supporting portions 120a and 120b, respectively. That is, each of the first and second magnetic field generators 130a and 130b may be disposed behind each of the first and second targets 110a and 110b.

In example embodiments, the first magnetic field generator 130a may include a plurality of magnets which may be disposed in the shape of a ring that surrounds the edge of the first supporting portions 120a, and the second magnetic field generator 130b may include a plurality of magnets which may be disposed in the shape of a ring that surrounds the edge of the second supporting portions 120b. Further, additional magnets (not illustrated) may be disposed on the centers of the first and second supporting portions 120a and 120b. For example, the magnets may be in shape of bar magnets.

The first magnetic field generator 130a and the second magnetic field generator 130b may have opposing polarities. For example, the first magnetic field generator 130a adjacent to the first target 110a may have an N-pole downwards, and the second magnetic field generator 130b adjacent to the second target 110b may have an S-pole upwards. Therefore, a magnetic line of force generated by the first and second magnetic field generators 130a and 130b may be aligned substantially perpendicular to the front surfaces of the first and second targets 110a and 110b.

In other example embodiments, the first and second magnetic generators 130a and 130b may rotate about an axis extending in the first direction. Particularly, the first and second magnetic generators 130a and 130b may rotate in a direction different from that of the sheet 70. That is, when the sheet 70 is transported in a clockwise direction, the first and second magnetic generators 130a and 130b may rotate in a counter clockwise direction. Therefore, uniformity of the magnetic field may be improved.

The first shield portion 140a and the second shield portion 140b may be disposed in the front of and the side of the first target 110a and the second target 110b, respectively. The first and second shield portions 140a and 140b may be grounded and may be serve as an anode. Alternatively, the first and second targets 110a and 110b may receive a voltage from a power supply unit 160, and may serve as a cathode. Each of the first and second shield portions 140a and 140b may include the same material as that of the first and second targets 110a and 110b, thereby thus preventing contamination.

The power supply unit 160 may generate a direct current (DC) voltage, a radio frequency (RF) voltage, a pulse direct current (DC) voltage power, or the like. The power supply unit 160 may apply a voltage to the first and second targets 110a and 110b, discharge of a gas may occur, and electrons generated due to the discharge may collide with an Ar gas in the chamber so that Ar ions and plasma may be generated. Plasma may be confined in a space 105 between the first target 110a and the second target 110b due to the magnetic field generated by the first and second magnetic field generators 130a and 130b, as described above. Plasma may include gamma-electrons, negative ions, positive ions, or the like.

Electrons in the plasma generated by the sputtering unit 100 may form a high-density plasma while making a rotating motion along a magnetic force line between the first and second targets 110a and 110b that face each other. Electrons in the plasma may simultaneously sustain the high-density plasma while making a reciprocating motion due to the negative voltage applied to each of the first and second targets 110a and 110b.

In this case, the ion particles having a relatively high energy may be accelerated to the opposite targets 110a and 110b and may be confined in plasma formed in the space 105, so that the high energy ion particles may not damage the sheet 70. Therefore, a layer may be formed on the sheet 70 by a diffusion of neutral particles having relatively small energy and moving in a direction substantially perpendicular to the first direction. Accordingly, when comparing the conventional sputtering system, damage by plasma, i.e., damage to the sheet 70 due to a collision of particles having high energy, may be reduced, and the layer having higher quality may be formed on the sheet 70.

Referring to FIG. 3, the fixing frame 150 may include an upper portion 152, a lower portion 154 and connection portions 156.

In example embodiments, the upper portion 152 and the lower portion 154 may have a ring-shape, and may include the same material. When viewed in the first direction, inner diameters of the upper portion 152 and the lower portion 154 may be substantially larger than diameters of the first and second targets 110a and 110b. Further, the upper portion 152 may be spaced apart from the lower portion 154 in the first direction.

The connection portions 156 may connect the lower portion 154 with the upper portion 152. In example embodiments, each of the connection portions may have a predetermined width and may extend in the first direction. Therefore, openings 158 may be disposed between the connection portions 156. The openings 158 may be defined by the upper portion 152, the lower portion 154, and the connection portions 156. That is, the top edge of the opening 158 may be defined by the upper portion 152, the bottom edge of the opening 158 may be defined by the lower portion 154, and the side edge of the opening 158 may be defined by the connection portions 156. The width of the opening 158 may be substantially larger than the width of the connection portions 156. That is, area of the opening 158 may be substantially larger than that of the connection portions 156.

In example embodiments, the upper portion 152, the lower portion 154, and the connection portions 156 may be integral. The fixing frame 150 may include a material having a relatively small thermal expansion coefficient. For example, the fixing frame 150 may include an alloy of Fe—Ni such as invar.

The fixing frame 150 may surround a side of the space 105 between the first target 110a and the second target 110b. Further, the fixing frame 150 may rotate about an axis extending in the first direction. When the first and second targets 110a and 110b have a circular planar shape, the rotation axis of the fixing frame 150 may meet at centers of the first target 110a and a center of the second target 110b.

The relation between the fixing frame 150 and the sheet 70 may be described with reference to FIGS. 1 and 2. The fixing frame 150 may serve to support the sheet 70 supplied from the first supporting roller 30. That is, the sheet 70 may directly contact the upper portion 152, the lower portion 154, and the connection portion 156 of the fixing frame 150, so that the sheet 70 moves around the sputtering unit 100 as the fixing frame 150 rotates. The fixing frame 150 may be disposed between the sheet 70 and the space 105.

In this case, a surface of the sheet 70, which directly contacts the fixing frame 150, may be defined as a first surface of the sheet 70. The fixing frame 150 may include the openings 158, so that the first surface of the sheet 70 may be exposed to the sputtering unit 100 (that is, the space 105) by the openings 158. Therefore, a layer may be formed on the first surface of the sheet 70 exposed by the openings 158 by the sputtering unit 100.

Depending on the location of the first and second supporting rollers 30 and 50, the sheet 70 may surround above about 50% of the periphery of the fixing frame 150. For example, the sheet 70 may surround above about 80% of the periphery of the fixing frame 150. That is, an angle θ made by the rotation axis of the fixing frame 150 and points of contact between the fixing frame 150 and the sheet 70 may be less than about 72 degrees. Therefore, a relatively large area may be used for the sputtering process.

During the sputtering process, particles of the target material generated in the space 105 between the first and second targets 110a and 110b may be diffused in any directions substantially perpendicular to the first direction. In the case of conventional sputtering apparatus, a relatively small portion, e.g. less than 50% of the periphery, may be used for the sputtering process, so that particles which may be diffused into other area may not be used to form the layer. In contrast, as noted above, according to example embodiment, more than 50% of the periphery, e.g., more than 80% of the periphery, may be used for the sputtering process. The efficiency of the sputtering process may be improved.

According to example embodiments, the sputtering apparatus may include the sputtering unit 100, the unwinding unit 20, and the winding unit 60 for continuously transporting the sheet 70, and the sputtering unit 100 may include the first target 110a and the second target 110b, which may face each other and may be spaced apart from each other. The fixing frame 150 surrounding the space 105 may support the sheet 70, so that the sheet 70 may surround above about 50% of the periphery of the space 105. Therefore, waste of the target material may be reduced, and a space for the sputtering apparatus may be saved by using a relatively large portion of the periphery of the space 105. Further, the sheet 70 may be continuous supplied, so that the sputtering speed may be improved.

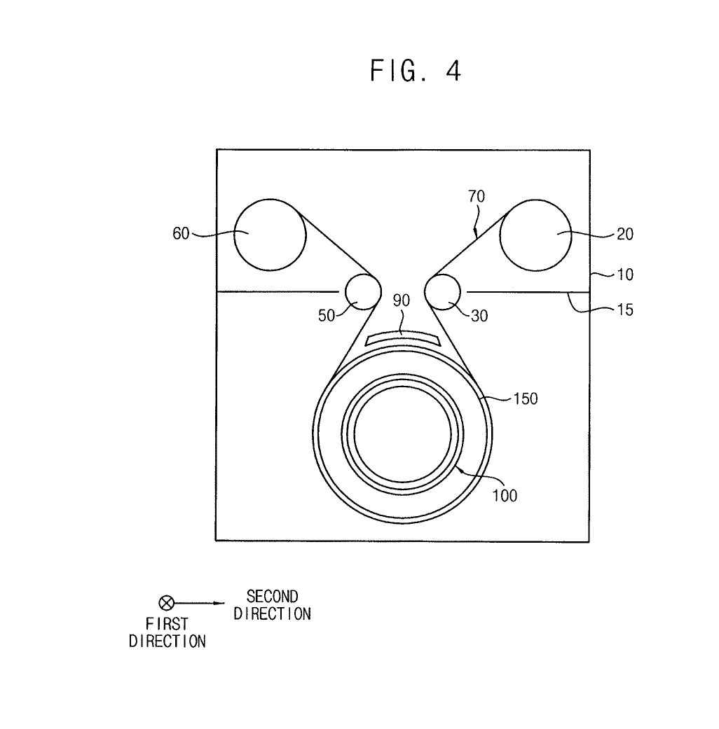

FIG. 4 is a plan view illustrating a sputtering apparatus in accordance with example embodiments. The sputtering apparatus of FIG. 4 may be substantially the same as or substantially similar to that described with reference to FIGS. 1 to 3 except for a third shield portion 90. Thus, like reference numerals refer to like elements, and repetitive explanations thereon may be omitted herein.

Referring to FIG. 4, the sputtering apparatus may include the vacuum chamber 10, the unwinding unit 20, the winding unit 60, the sputtering unit 100, and the fixing frame 150.

The vacuum chamber 10 may be divided into the first region for the sputtering unit 100 and the second region for the unwinding unit 20 and the winding unit 60 by a partition wall 15. An inner space of the vacuum chamber 10 may be maintained at a vacuum pressure.

The unwinding unit 20 may serve the supply a sheet 70 to the sputtering unit 100. The sputtering unit 100 may form a layer on the sheet 70, which may be supplied from the unwinding unit 20. The winding unit 60 may serve to receive the sheet 70 from the sputtering unit 100. The sputtering unit 100 may be substantially the same as or substantially similar to that described with reference to FIGS. 1 to 3. Each of the unwinding unit 20 and the winding unit 60 may include a rotation shaft extending in a first direction. As the rotation shaft rotates, the sheet 70 may be continuously transported from the unwinding unit 20 to the winding unit 60 through the sputtering unit 100.

The sheet 70 may have a predetermined width and may extend in a direction. For example, the sheet 70 may include a material having a predetermined flexibility such as PET, PEN, PA, PC, PES, PI, etc.

Between the unwinding unit 20 and the winding unit 60, a plurality of supporting rollers may be disposed to guide the sheet 70. In example embodiments, the first supporting roller 30 may be disposed between the unwinding unit 20 and the sputtering unit 100, and the second supporting roller 50 may be disposed between the sputtering unit 100 and the winding unit 60.

Referring now to FIG. 4, the sputtering unit 100 may include at least two targets facing each other, and the third shield portion 90 may be disposed to partially cover a side of a space between the targets. The third shield portion 90 may partially cover the side of the space where the sheet 70 is not disposed. During the sputtering process, particles of the target material generated in the space between the targets may be diffused in any directions substantially perpendicular to the first direction. Therefore, the particles of the target material may move in a direction where the sheet 70 is not disposed. The third shield portion 90 may prevent the particles of the target material from entering the second region of the vacuum chamber 10. Therefore, the vacuum chamber 10 may not be contaminated by the target material.

According to example embodiments, the fixing frame 150 surrounding the space between the targets may support the sheet 70, so that the sheet 70 may surround above about 50% of the periphery of the space. Therefore, waste of the target material may be reduced, and a space for the sputtering apparatus may be saved by using a relatively large portion of the periphery of the space. Further, the third shield portion 90 may prevent the particles of the target material from contaminating the vacuum chamber 10.

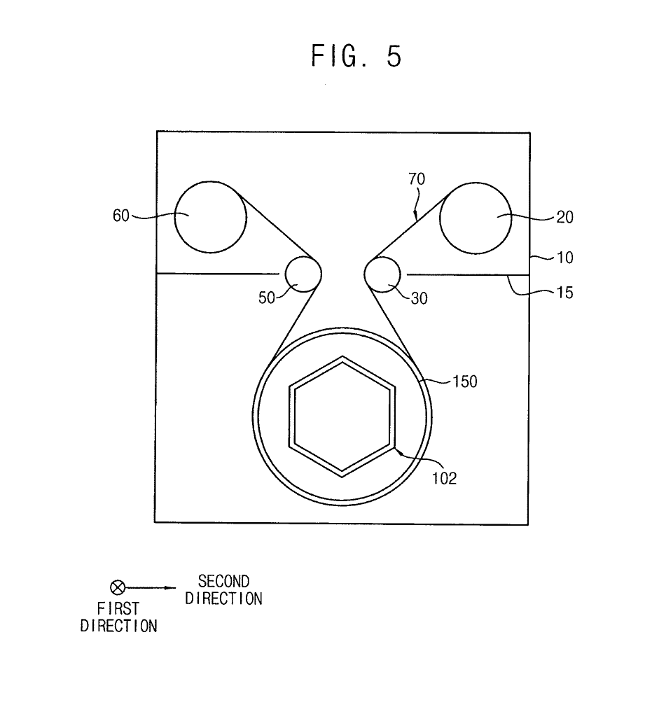

FIG. 5 is a plan view illustrating a sputtering apparatus in accordance with example embodiments. The sputtering apparatus of FIG. 5 may be substantially the same as or substantially similar to that described with reference to FIGS. 1 to 3 except for a planar shape of a sputtering unit 102. Thus, like reference numerals refer to like elements, and repetitive explanations thereon may be omitted herein.

Referring to FIG. 5, the sputtering apparatus may include the vacuum chamber 10, the unwinding unit 20, the winding unit 60, a sputtering unit 102, and the fixing frame 150.

In example embodiments, a first target structure (not illustrated) and a second target structure (not illustrated) of the sputtering unit 102 may have a hexagonal planar shape. Therefore, targets (not illustrated) of the sputtering unit 102 also may have a hexagonal planar shape.

However, embodiments are not limited to FIG. 5, and the targets also may have any polygonal planar shape, e.g., square, pentagon, octagon, an elliptical planar shape, and so forth.

According to example embodiments, the fixing frame 150 surrounding a space between targets may support the sheet 70, so that the sheet 70 may surround above about 50% of the periphery of the space. Therefore, waste of the target material may be reduced, and a space for the sputtering apparatus may be saved by using a relatively large portion of the periphery of the space.

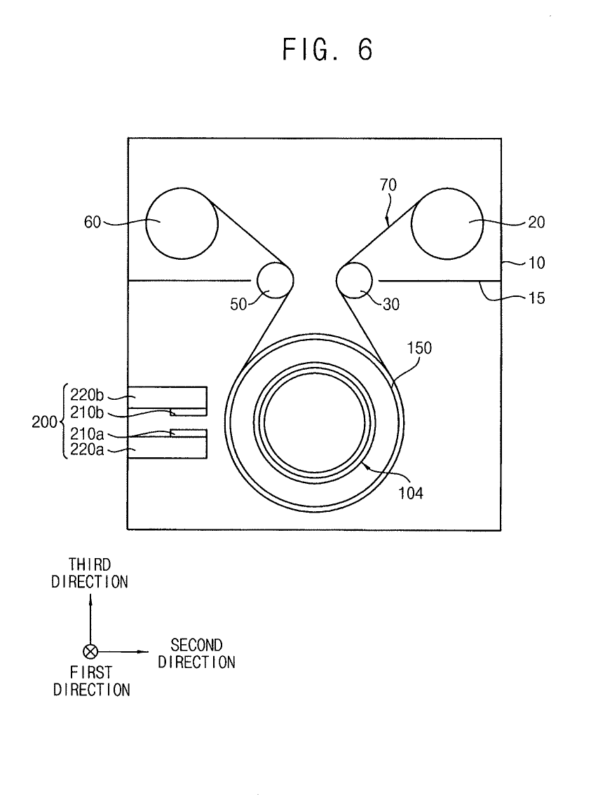

FIG. 6 is a plan view illustrating a sputtering apparatus in accordance with example embodiments. The sputtering apparatus of FIG. 6 may be substantially the same as or substantially similar to that described with reference to FIGS. 1 to 3 except for a second sputtering unit 200. Thus, like reference numerals refer to like elements, and repetitive explanations thereon may be omitted herein.

Referring to FIG. 6, the sputtering apparatus may include the vacuum chamber 10, the unwinding unit 20, the winding unit 60, a first sputtering unit 104, a second sputtering unit 200, and the fixing frame 150.

The vacuum chamber 10 may be divided into the first region for the sputtering unit 100 and the second region for the unwinding unit 20 and the winding unit 60 by a partition wall 15. An inner space of the vacuum chamber 10 may be maintained at a vacuum pressure.

The sheet 70 may be transported from the unwinding unit 20 to the winding unit 60 through the first sputtering unit 104. The sputtering unit 104 may be substantially the same as or substantially similar to that described with reference to FIGS. 1 to 3.

The second sputtering unit 200 may be opposed to the first sputtering unit 104, and the sheet 70 may be disposed between the first sputtering unit 104 and the second sputtering unit 200. That is, a first surface of the sheet 70 may face the first sputtering unit 104, and a second surface of the sheet 70 opposing to the first surface may face the second sputtering unit 200.

The second sputtering unit 200 may include a plurality of targets that face each other. In example embodiments, the second sputtering unit 200 may include a third target 210a and a fourth target 210b facing each other. The second sputtering unit 200 may also include a third supporting portion 220a and a fourth supporting portion 220b for supporting the third target 210a and the fourth target 210b, respectively. The second sputtering unit 200 may also include a magnetic field generator (not illustrated) behind each of the third and the fourth targets 210a and 210b.

In example embodiments, the third target 210a may be spaced apart from the fourth target 210b in a third direction substantially perpendicular to the first direction. Therefore, a layer may be formed on the second surface of the sheet 70 by diffusion of particles of target material generated in a space between the third target 210a and the fourth target 210b.

According to example embodiments, the sputtering apparatus may include the first sputtering unit 104 for forming a first layer on the first surface of the sheet 70 and the second sputtering unit 200 for forming a second layer on the second surface of the sheet 70. Therefore, the efficiency of the sputtering process may be improved.

Embodiments may be applied to an apparatus for manufacturing a system having a flexible sheet as a substrate. For example, embodiments may be applied to manufacture an organic light emitting diode device including a flexible substrate or a solar cell including a flexible substrate.

By way of summation and review, according to example embodiments, a sputtering apparatus may include a sputtering unit, an unwinding unit and a winding unit for continuously transporting a sheet, and a fixing frame. The sputtering unit may include a first target and a second target, which may face each other and may be spaced apart from each other. The fixing frame surrounding a space between the first target and the second target may support the sheet, so that the sheet may surround above about 50% of a periphery of the space. Therefore, waste of the target material may be reduced, and a space for the sputtering apparatus may be saved by using a relatively large portion of the periphery of the space between the first target and the second target. Further, the sheet may be continuous supplied, so that the sputtering speed may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A sputtering apparatus, comprising:
a sputtering unit configured to form a layer on a sheet;
an unwinding unit continuously supplying the sheet to the sputtering unit;
a winding unit continuously receiving the sheet from the sputtering unit,
wherein the sputtering unit includes:
a first target;
a second target spaced apart from the first target in a first direction, the first target and the second target facing each other; and
a magnetic field generator disposed behind each of the first target and the second target; and
a fixing frame surrounding a space between the first target and the second target, the fixing frame rotating about an axis extending in the first direction.

2. The sputtering apparatus of claim 1, wherein the fixing frame supports the sheet, and wherein the sheet is transported by rotation of the fixing frame.

3. The sputtering apparatus of claim 2, wherein the fixing frame is disposed between the sheet and the space.

4. The sputtering apparatus of claim 3, wherein the fixing frame comprises:
a lower portion having a ring-shape;
an upper portion having a ring-shape, the upper portion being spaced apart from the lower portion in the first direction; and
at least two connection portions connecting the lower portion with the upper portion, wherein the lower portion, the upper portion, and the connection portions define a plurality of openings.

5. The sputtering apparatus of claim 4, wherein the sheet is exposed by the openings of the fixing frame to the space between the first target and the second target.

6. The sputtering apparatus of claim 5, wherein the sheet is exposed by the openings of the fixing frame to more than 50% of a periphery of the space between the first target and the second target.

7. The sputtering apparatus of claim 4, wherein the lower portion, the upper portion, and the at least two connection portions are all integral.

8. The sputtering apparatus of claim 1, wherein each of the first target and the second target has a circular planar shape.

9. The sputtering apparatus of claim 8, wherein the rotation axis of the fixing frame meets at a center of the first target and a center of the second target.

10. The sputtering apparatus of claim 1, wherein each of the first target and the second target has an elliptical planar shape or a polygonal planar shape.

11. The sputtering apparatus of claim 1, wherein the sheet surrounds above 80% of a periphery of the fixing frame.

12. The sputtering apparatus of claim 1, wherein each of the unwinding unit and the winding unit includes a roller rotating about an axis extending in the first direction.

13. The sputtering apparatus of claim 1, wherein the sputtering unit is configured to form a first layer on a first surface of the sheet, the sputtering apparatus further comprising:
a second sputtering unit configured to form a second layer on a second surface of the sheet, the second surface opposing to the first surface.

14. The sputtering apparatus of claim 13, wherein the fixing frame supports the sheet, wherein the sheet is transported by a rotation of the fixing frame, and wherein the sheet surrounds above 80% of a periphery of the fixing frame.

15. The sputtering apparatus of claim 14, wherein the fixing frame comprises:
a lower portion having a ring-shape;
an upper portion having a ring-shape, the upper portion being spaced apart from the lower portion in the first direction; and
at least two connection portions connecting the lower portion with the upper portion,
and wherein the lower portion, the upper portion and the connection portions define a plurality of openings.

16. The sputtering apparatus of claim 15, wherein the first surface of the sheet is exposed by the openings of the fixing frame to the space between the first target and the second target.

17. The sputtering apparatus of claim 13, wherein each of the first target and the second target has a circular planar shape, an elliptical planar shape, or a polygonal planar shape.

18. The sputtering apparatus of claim 13, wherein the second sputtering unit comprises:
a third target;
a fourth target spaced apart from the third target in a second direction substantially perpendicular to the first direction, the first target and the second target facing each other; and
a magnetic field generator disposed behind each of the first target and the second target.

19. The sputtering apparatus of claim 1, further comprising a shield adjacent the fixing frame where the sheet does not surround the fixing frame.
